(19) United States
(12) Patent Application Publication
(10) Pub. No.: US 2020/0150270 A1
(43) Pub. Date: May 14, 2020

(54) INFRARED PROXIMITY SENSOR

(71) Applicant: LITE-ON SINGAPORE PTE. LTD., Singapore (SG)

(72) Inventors: TECK-CHAI GOH, Singapore (SG); Wei-Chee Lee, Singapore (SG); GUANG-LI SONG, SINGAPORE (SG); LAY-THANT KO, Singapore (SG); SIN-HENG LIM, SINGAPORE (SG)

(21) Appl. No.: 16/436,174

(22) Filed: Jun. 10, 2019

(30) Foreign Application Priority Data
Nov. 14, 2018 (CN) 201821877955.5

(51) Int. Cl. G01S 17/02; G01S 7/481; G01J 1/42

(52) U.S. Cl. CPC G01S 17/026; H01S 5/183; G01J 1/4204; G01S 7/4811

(57) ABSTRACT

An infrared proximity sensor includes a substrate, an emitting unit, a receiving unit, a packaging unit and an isolating unit. The substrate has a supporting surface and the supporting surface has an emitting region and a receiving region corresponding in position to the emitting region. The emitting unit is disposed on the emitting region. The receiving unit is disposed on the receiving region. The packaging unit includes a first package body and a second package body. The first package body covers the emitting unit and the second package body covers the receiving unit. The isolating unit is disposed between the first package body and the second package body. The substrate has a first side and a second side, and the first side has a length less than 1.5 mm.

### CROSS-REFERENCE TO RELATED PATENT APPLICATION

This application claims the benefit of priority to China Patent Application No. 201821877955.5, filed on Nov. 14, 2018 in People's Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a proximity sensor, and more particularly to an infrared proximity sensor which can avoid crosstalk.

### BACKGROUND OF THE DISCLOSURE

A proximity sensor refers to a sensor for detecting the distance of an object. A common example of the use of the proximity sensor is being employed in a smart phone to avoid mistouches on a touch screen when speaking on the phone. The working principle of the proximity sensor is emitting an electromagnetic field or light beam and analyzing a change by a receiving unit so as to determine the proximity or presence of an object.

Since the touch screen is becoming larger and an edge frame of the touch screen is becoming narrower, the space for installation of components in the conventional smart phone has decreased. The touch screen is currently provided with an ambient light sensor which cooperates with the proximity sensor. The ambient light sensor is configured to adjust the brightness of the touch screen, so that the brightness of the touch screen can be changed according to changes in ambient light levels so as to achieve the effects of energy saving and eye protection. The proximity sensor is configured to detect whether an object is in front of the touch screen.

The conventional proximity sensor is provided with a shielding case to eliminate interference of external lights such as lamplight and sunlight, so as to avoid crosstalk. However, the proximity sensor with the shielding case cannot decrease in volume or thickness. Therefore, in order to meet the requirements of current smart phones, reducing the volume or thickness of the proximity sensor has become one of the important issues to be solved.

### SUMMARY OF THE DISCLOSURE

In response to the above-referenced technical inadequacies, the present disclosure provides an infrared proximity sensor which can avoid crosstalk without a shielding case.

In one aspect, the present disclosure provides an infrared proximity sensor which includes a substrate, an emitting unit, a receiving unit, a packaging unit and an isolating unit. The substrate has a supporting surface and the supporting surface has an emitting region and a receiving region corresponding in position to the emitting region. The emitting unit is disposed on the emitting region. The receiving unit is disposed on the receiving region. The packaging unit includes a first package body and a second package body. The first package body covers the emitting unit and the second package body covers the receiving unit. The isolating unit is disposed between the first package body and the second package body. The substrate has a first side and a second side, and the first side has a length less than 1.5 mm. Therefore, the volume of the sensor can be effectively reduced.

In certain embodiments, the top end of the first package body has a light output surface, the top end of the second package body has a light input surface, and the light output surface of the first package body and the light input surface of the second package body are exposed to an exterior environment.

In certain embodiments, the total thickness of the substrate and the packaging unit is between 0.7 mm and 1.0 mm.

In certain embodiments, the isolating unit is a shielding layer.

In certain embodiments, the isolating unit is an air groove and the air groove is a U-shaped or V-shaped groove. Furthermore, the U-shaped groove has a curved surface with a diameter less than 1 mm.

In certain embodiments, the isolating unit is an encapsulant layer.

In certain embodiments, the second package body further includes a circular trench surrounding the receiving unit.

In certain embodiments, the emitting unit is a vertical cavity surface emitting laser (VCSEL).

In certain embodiments, the receiving unit is an ambient light sensor (ALS) or an RGB sensor. One of the advantages of the present disclosure is that the infrared proximity sensor of the present disclosure, in which the isolating unit is disposed between the first package body and the second package body and the substrate has opposite first and second sides, can omit the shielding case and thus has a reduced size. The first side of the substrate has a length less than 1.5 mm and the total thickness of the substrate and the packaging unit is between 0.7 mm and 1.0 mm. Furthermore, the crosstalk between the emitting unit and the receiving unit and exterior interference can be avoided.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a schematic view of an infrared proximity sensor of the present disclosure.

FIG. 2 is a side sectional view of the infrared proximity sensor of the present disclosure.

FIG. 3A is a side sectional view of the infrared proximity sensor according to an embodiment of the present disclosure.

FIG. 3B is a side sectional view of the infrared proximity sensor according to another embodiment of the present disclosure.

FIG. 3C is a side sectional view of the infrared proximity sensor according to still another embodiment of the present disclosure.

FIG. 3D is a perspective view of the infrared proximity sensor according to the embodiment depicted by FIG. 3C of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

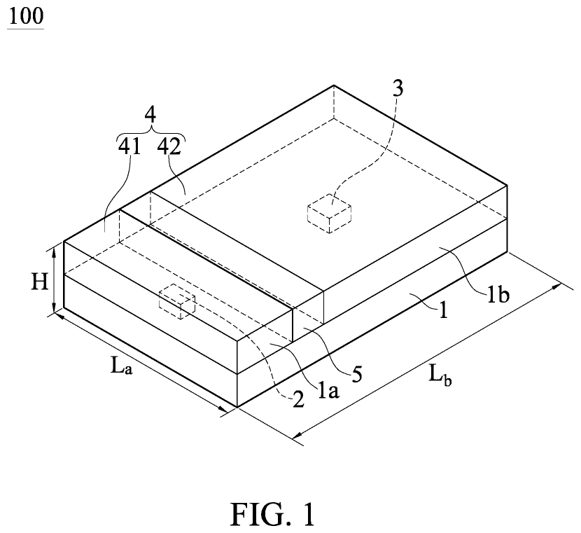

Referring to FIG. 1, a schematic view of an infrared proximity sensor according to an exemplary embodiment of the present disclosure is provided. The infrared proximity sensor 100 includes a substrate 1, an emitting unit 2, a receiving unit 3, a packaging unit 4 and an isolating unit 5.

The substrate 1 has a supporting surface and the supporting surface has an emitting region 1a and a receiving region 1b corresponding in position to the emitting region 1a. The substrate 1 can be a common PCB, but is not limited thereto. More specifically, the emitting region 1a is located near, but not connected to, the receiving region 1b. The substrate 1 has a first side Lₐ and a second side L_{b}. The substrate 1 is cuboid in shape, in which the first side Lₐ is a short side and the second side L_{b} is a long side, and the first side Lₐ has a length less than 1.5 mm. Furthermore, the total thickness H of the substrate 1 and the packaging unit 4 is between 0.7 mm and 1.0 mm.

The emitting unit 2 is disposed on the emitting region 1a. The receiving unit 3 is disposed on the receiving region 1b. Furthermore, the substrate 1 can be provided with a control circuit (not shown) for controlling the operation of the emitting unit 2 and the receiving unit 3.

More specifically, the emitting unit 2 can be a vertical cavity surface emitting laser (VCSEL). The receiving unit 3 can be an ambient light sensor (ALS), an RGB sensor, or the combination thereof.

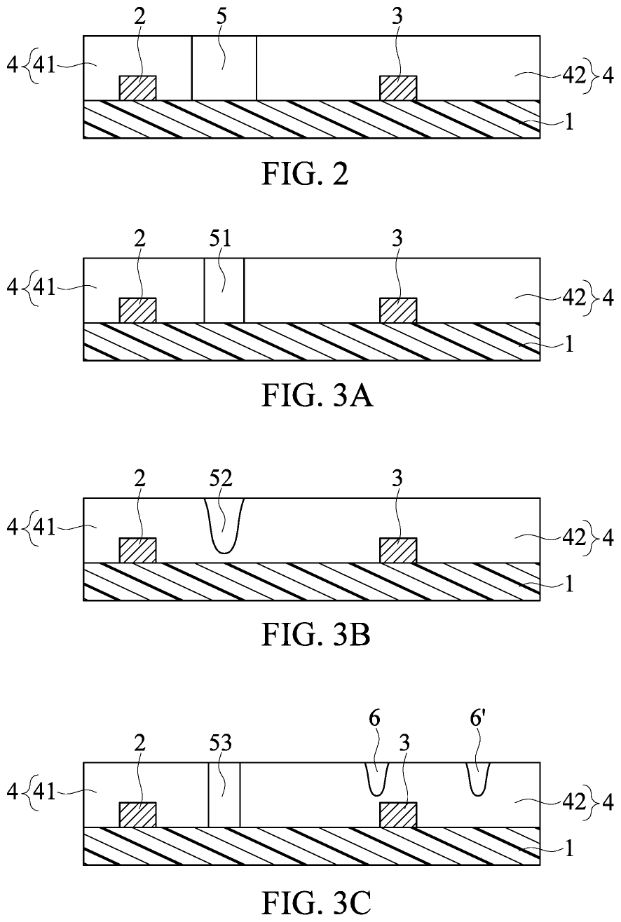

The packaging unit 4 includes a first package body 41 and a second package body 42. The first package body 41 covers the emitting unit 2, and the second package body 42 covers the receiving unit 3. The top end of the first package body 41 has a light output surface, the top end of the second package body 42 has a light input surface, and the light output surface of the first package body 41 and the light input surface of the second package body 42 are exposed to an exterior environment. The first package body 41 and the second package body 42 can be made of a transparent packaging material. In a certain embodiment of the present disclosure, the transparent packaging material can be an infrared-shielding compound with a transmittance between 60% and 80% at 940 nm. Accordingly, crosstalk in the packaging material due to internal reflection and scattering can be prevented. The transparent packaging material can be a glass, epoxy, silicone, urea resin, or acrylic resin system, but is not limited thereto. In practice, the light output surface of the first package body 41 can be an aspheric surface, cambered surface, parabolic surface, hyperbolic surface, or free-form surface so as to increase the light intensity of the emitting unit 2. The isolating unit 5 as shown in FIG. 2, which is a side sectional view according to a certain embodiment of the present disclosure, is disposed between the first package body 41 and the second package body 42. Therefore, the emitting region 1a is located near, but not connected to, the receiving region 1b.

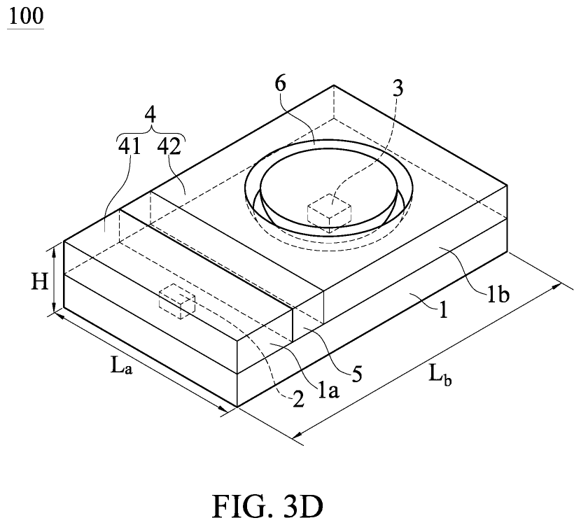

In another embodiment of the present disclosure, the isolating unit 5 as shown in FIG. 3A can include a shielding layer 51. The shielding layer 51 is made of a non-transparent material which can be selected from plastics and metals such as copper, aluminum, silver, gold, or the combination thereof, but is not limited thereto. More specifically, the shielding layer 51 can be disposed on the substrate 1 such that the emitting region 1a is in proximity to the receiving region 1b, rather than adjoining to the receiving region 1b.

In an embodiment of the present disclosure, the isolating unit 5 can include an air groove 52, and the air groove 52 is a U-shaped or V-shaped groove. FIG. 3B shows an implementation of the air groove 52 which is a U-shaped groove. More specifically, the air groove 52 does not extend to the substrate 1 in depth, thereby having a better mechanical strength. More specifically, the U-shaped groove has a curved surface with a diameter less than 1 mm.

In still another embodiment of the present disclosure, the isolating unit 5 as shown in FIG. 3C can include an encapsulant layer 53 which is made of the same material as the first package body 41 and the second package body 42. Furthermore, the second package body 42 further includes a circular trench 6 surrounding the receiving unit 3. The circular trench 6(6′) as shown in FIG. 3D, which is a perspective view according to the same embodiment as FIG. 3C, surrounds the receiving unit 3. More specifically, the circular trench 6 is a U-shaped trench surrounding the receiving unit 3.

The conventional proximity sensor mainly uses an additional shielding case to avoid crosstalk between the emitting unit and the receiving unit, and to shield from exterior interferences. However, the shielding case having a thickness of about 100 mm cannot reduce the spacing between the emitting region and the receiving region and the size of the proximity sensor. In contrast, the infrared proximity sensor 100 of the present disclosure omits the shielding case and thus has a reduced size. Therefore, the first side Lₐ of the substrate 1 has a length less than 1.5 mm, and preferably less than 1.44 mm. The total thickness of the substrate 1 and the packaging unit 4 is between 0.7 mm and 1.0 mm, preferably 0.7 mm.

One of the advantages of the present disclosure is that the infrared proximity sensor of the present disclosure, in which the isolating unit is disposed between the first package body and the second package body and the substrate has opposite first and second sides and the length of the first side is less than 1.5 mm, can omit the shielding case and thus has a reduced size. The first side of the substrate has a length less than 1.5 mm and the total thickness of the substrate and the packaging unit is between 0.7 mm and 1.0 mm. Furthermore, the crosstalk between the emitting unit and the receiving unit and exterior interference can be avoided.

Furthermore, the infrared proximity sensor according to an embodiment of the present disclosure, in which the isolating unit is an air groove, can minimize the crosstalk caused by ambient lights and sidelights. The infrared proximity sensor according to a certain embodiment of the present disclosure, in which the second package body further includes a circular trench surrounding the receiving unit, can effectively prevent interferences by shielding off the exterior light.

The packaging material of the present disclosure is an infrared-shielding compound with a transmittance between 60% and 80% at 940 nm, such that crosstalk in the packaging material due to internal reflection and scattering can be prevented. Therefore, the infrared proximity sensor can have an improved accuracy and sensitivity.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An infrared proximity sensor, comprising:
a substrate having a supporting surface, the supporting surface having an emitting region and a receiving region corresponding in position to the emitting region;
an emitting unit disposed on the emitting region;
a receiving unit disposed on the receiving region;
a packaging unit including a first package body and a second package body, the first package body covering the emitting unit, the second package body covering the receiving unit; and
an isolating unit disposed between the first package body and the second package body;
wherein the substrate has a first side and a second side, and the first side has a length less than 1.5 mm.

2. The infrared proximity sensor according to claim 1, wherein the top end of the first package body has a light output surface, the top end of the second package body has a light input surface, and the light output surface of the first package body and the light input surface of the second package body are exposed to the exterior environment.

3. The infrared proximity sensor according to claim 1, wherein the total thickness of the substrate and the packaging unit is between 0.7 mm and 1.0 mm.

4. The infrared proximity sensor according to claim 1, wherein the isolating unit is a shielding layer.

5. The infrared proximity sensor according to claim 1, wherein the isolating unit is an air groove, and the air groove is a U-shaped or V-shaped groove.

6. The infrared proximity sensor according to claim 5, wherein the U-shaped groove has a curved surface with a diameter less than 1 mm.

7. The infrared proximity sensor according to claim 1, wherein the isolating unit is an encapsulant layer.

8. The infrared proximity sensor according to claim 7, wherein the second package body further includes a circular trench surrounding the receiving unit.

9. The infrared proximity sensor according to claim 1, wherein the emitting unit is a vertical cavity surface emitting laser (VCSEL).

10. The infrared proximity sensor according to claim 1, wherein the receiving unit is an ambient light sensor (ALS) or an RGB sensor.
